(19) United States
(12) Patent Application Publication
(10) Pub. No.: US 2006/0148244 A1
(43) Pub. Date: Jul. 6, 2006

(54) Method for cleaning a semiconductor substrate

(75) Inventor: Jea Hee Kim, Yeoju-gun (KR)

Correspondence Address: MCKENNA LONG & ALDRIDGE LLP, 1900 K STREET, NW, WASHINGTON, DC, 20006, US

(73) Assignee: DONGBUANAM SEMICONDUCTOR INC., Kangnam-Ku (KR)

(21) Appl. No.: 11/320,483

(22) Filed: Dec. 29, 2005

(30) Foreign Application Priority Data
Dec. 30, 2004 (KR) 10-2004-117263

(51) Int. Cl. H01L 21/4763; H01L 21/302

(52) U.S. Cl. 438/639; 438/749

(57) ABSTRACT

A method for cleaning a semiconductor substrate, on which a semiconductor device is formed having a damascene structure using a copper line, that may prevent an abrasion of the substrate by using a simplified cleaning process. The method includes cleaning a surface of the semiconductor substrate having a copper line with a first cleaning solution including HF and ultra pure water; and cleaning the surface of the semiconductor substrate having the copper line with a mixture of a second cleaning solution including H₂O₂ and ultra pure water and a third cleaning including TMAH and ultra pure water.

### CROSS REFERENCE TO RELATED APPLICATION

This application claims the benefit of Korean Patent Application No. 10-2004-0117263, filed on Dec. 30, 2004, which is hereby incorporated by reference for all purposes as if fully set forth herein.

### BACKGROUND OF THE INVENTION

1. Field of the Invention

The present invention relates to a method for cleaning a semiconductor substrate with a simplified process while preventing abrasion of a rear surface of the substrate.

2. Discussion of the Related Art

In fabricating a semiconductor device, a conductive metal layer is deposited by chemical vapor deposition on an insulating (or low dielectric) layer formed on a substrate such as a silicon wafer. An etching mask of photoresist is formed on the insulating layer, which is etched to form minute features such as a contact pad and wiring, and then the photoresist is stripped. However, when the features are very small, higher line resistance (the resistance of the patterned metal layer) line delays caused by a line capacitance, and other problems tend to occur. The line resistance may be reduced by the use of copper rather than aluminum as the conductive metal layer.

The above semiconductor device may incorporate an aluminum line (i.e., a metal line formed mainly of aluminum or an aluminum alloy) or a copper line (i.e., a metal line formed mainly of copper). In forming a metal line of copper, a copper layer may be etched or a dual damascene method may be employed to form a multi-layered copper structure without etching the copper.

In a typical dual damascene method, after forming a copper layer on a substrate, interposed layers such as a low-dielectric layer and an insulating layer are stacked on the copper layer. A first photoresist pattern is formed on the stack to serve as an etching mask for via-hole formation, whereby the low-dielectric layer and the insulating layer are etched to open the via-hole, which will be filled with the copper layer to form an electrical connection (contact plug). A sacrificial layer of alkoxysilane is formed inside the via-hole after the first photoresist pattern is stripped. A second photoresist pattern (etching mask), for the formation of a trench pattern coincident with the via-hole, is then formed on the uppermost layer of the stacked low-dielectric and insulating layers, and the sacrificial layer and the low-dielectric layer are partially etched to form the trench, which, when filled with copper, will serve as a line of copper wiring. The remainder of the sacrificial layer is then removed from the via-hole. After stripping the second photoresist pattern, the via-hole and trench are both filled with copper, which is planarized by chemical-mechanical polishing, to form the multi-layered structure of a copper line.

During the chemical-mechanical polishing of the copper filling the via-hole and trench, particles generated from the copper deposition and copper line formation may reach the rear surface of the substrate and penetrate the surface, thereby contaminating the substrate. To prevent such contamination, a cleaning process for removing the particles is performed. First, the rear surface of the substrate is cleaned with a solution of hydrogen peroxide (H₂O₂) and ultra pure water, thus oxidizing the surface and forming an oxide layer. The oxidized rear surface is then cleaned with a solution of hydrofluoric acid (HF) and ultra pure water, to remove the oxide layer and expose the underlying surface. Finally, the copper particles are removed from the substrate using a third solution of tetramethylammonium hydroxide (TMAH) and ultra pure water.

In cleaning the substrate surface as above, the solution of hydrofluoric acid and ultra pure water is applied following the formation of the copper line. As a result, the surface of the semiconductor substrate may be abraded.

### SUMMARY OF THE INVENTION

Accordingly, the present invention is directed to a method for cleaning a semiconductor substrate that substantially obviates one or more problems due to limitations and disadvantages of the related art.

An advantage of the present invention is that it provides a method for cleaning a semiconductor substrate, that prevents abrasion of a rear surface of the substrate, using a first cleaning solution including HF and ultra pure water to clean the rear surface of the substrate when forming a copper line and using both a second cleaning solution including H₂O₂ and ultra pure water and a third cleaning solution including TMAH and ultra pure water in fabrication steps performed after forming the copper line.

Additional advantages and features of the invention will be set forth in part in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages in accordance with the purpose of the invention, as embodied and broadly described herein, a method for cleaning a semiconductor substrate having a semiconductor device, comprises cleaning a surface of the semiconductor substrate having a copper line with a first cleaning solution including HF and ultra pure water; and cleaning the surface of the semiconductor substrate having the copper line with a mixture of a second cleaning solution including H₂O₂ and ultra pure water and a third cleaning including TMAH and ultra pure water.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention.

In the drawings:

FIGS. 1A-1H are cross-sectional views of a semiconductor device of a dual damascene structure.

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

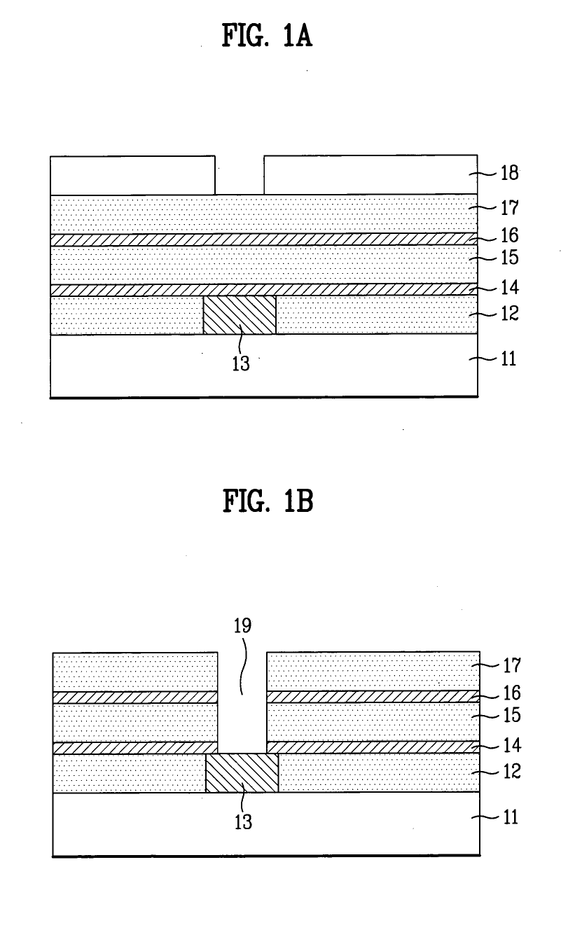

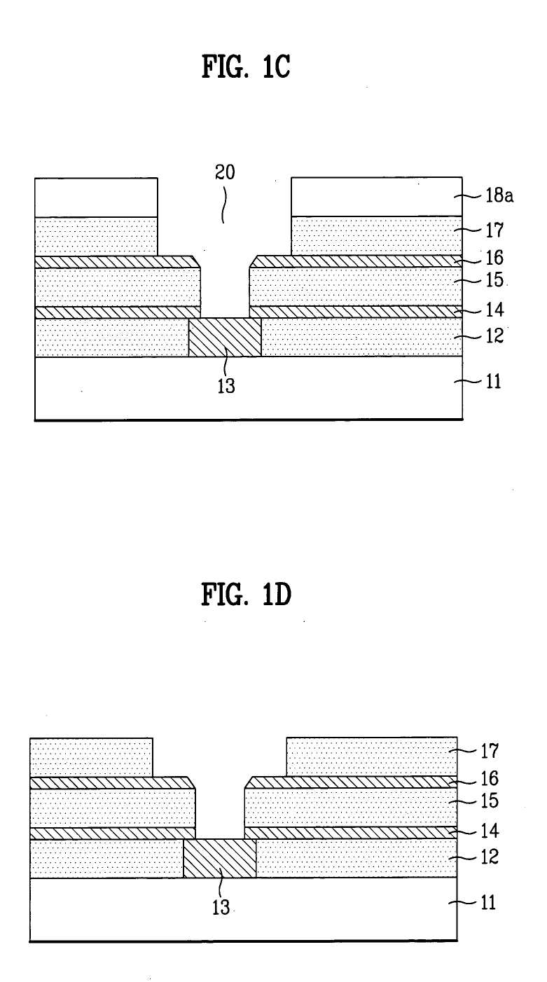

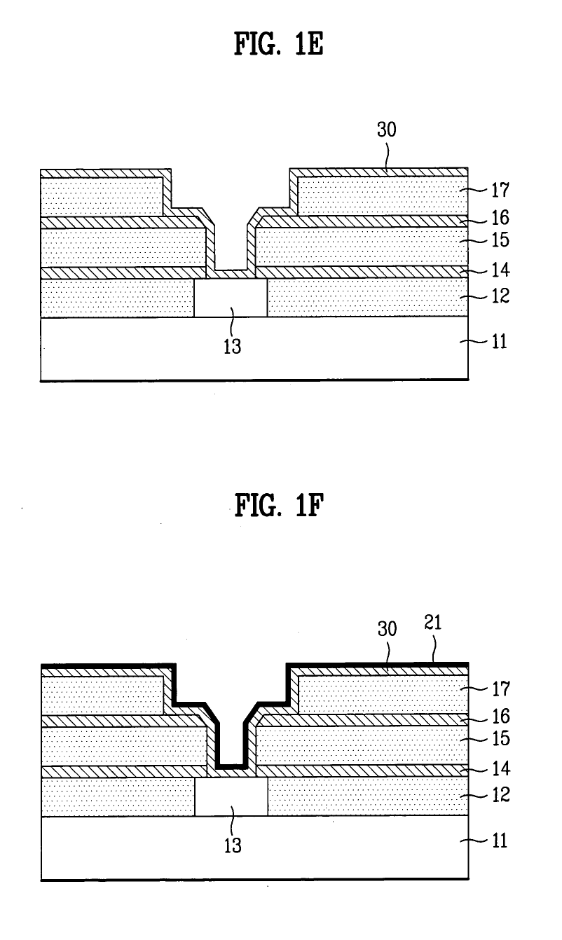

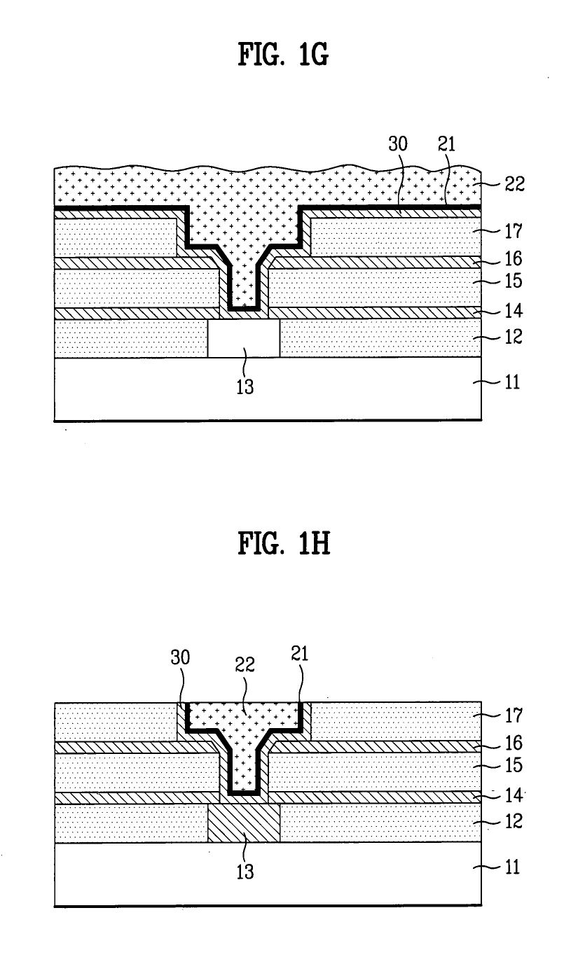

FIGS. 1A-1H illustrate a method for fabricating a semiconductor device of a dual damascene structure used to explain a method according to an exemplary embodiment of the present invention for cleaning a semiconductor substrate on which the device is formed.

As shown in FIG. 1A, a first insulating interlayer 12 is deposited on a semiconductor substrate 11 and is selectively etched using photolithography, thereby forming a via-hole for exposing a predetermined portion of the semiconductor substrate 11. The first insulating interlayer 12 is formed of an insulating material having an insulation constant below 3. A layer of copper is deposited on an entire surface of the semiconductor substrate 11 including the via-hole, and the deposited layer is planarized to leave the copper only inside the via-hole, thereby forming a lower metal layer 13. A first barrier layer 14, a second insulating interlayer 15, a second barrier layer 16, and a third insulating interlayer 17 are sequentially formed over the semiconductor substrate 11 including the lower metal layer 13. The second and third insulating interlayers 15 and 17 are formed of an insulating material having an insulation constant below 3, and the first and second barrier layers 14 and 16 are formed of a nitride material. A layer of photoresist is formed on the third insulating interlayer 17, and a photolithography (exposure and development) process is used to form a first photoresist pattern 18 for exposing a predetermined portion of the third insulating interlayer.

Referring to FIG. 1B, the third insulating interlayer 17, the second barrier layer 16, the second insulating interlayer 15, and the first barrier layer 14 are etched using the first photoresist pattern 18 as a mask, which is thereafter removed. As a result, a via-hole 19 for exposing the lower metal layer 13 is formed.

As shown in FIG. 1C, the entire surface of the semiconductor substrate 11 is coated with another layer of photoresist, which is patterned to form a second photoresist pattern 18a for exposing the via-hole 19 and a portion of the third insulating interlayer 17 adjacent the via-hole. Using the second photoresist pattern 18a as a mask, the third insulating interlayer 17 is selectively etched to expose the second barrier layer 16, thereby forming a trench 20.

As shown in FIG. 1D, the second photoresist pattern 18a is removed.

As shown in FIG. 1E, a diffusion layer 30 is formed on the inner surface of the via-hole 19, the inner surface of the trench 20, and the third insulating interlayer 17.

As shown in FIG. 1F, a copper seed layer 21 is formed on the diffusion layer 30.

As shown in FIG. 1G, a copper line 22 is formed to fill the via-hole 19 and the trench 20.

As shown in FIG. 1H, the copper line 22 is planarized by a chemical-mechanical polishing process, during which particles generated from the copper line 22 may reach the rear surface of the semiconductor substrate 11 and penetrate the surface.

When forming the copper line 22, the rear surface of the semiconductor substrate 11 is cleaned with a first cleaning solution including hydrofluoric acid (HF) and ultra pure water. In the subsequent steps, after forming the copper line 22, the rear surface of the semiconductor substrate 11 is cleaned with a mixture of a second cleaning solution and a third cleaning solution. The second cleaning solution is formed with hydrogen peroxide (H₂O₂) and ultra pure water, and the third cleaning solution is formed with tetramethylammonium hydroxide (TMAH) and ultra pure water.

Rather than using the first, second, and third cleaning solutions from the process for forming the copper line 22 to the final process for forming the semiconductor device, which can result in an abraded rear surface of the semiconductor device 11 due to the first cleaning solution, the method of the present invention uses the first cleaning solution only in the step of forming the copper line 22. In the subsequent steps, i.e., after forming the copper line 22, the rear surface of the semiconductor substrate 11 is cleaned with the second and third cleaning solutions. As a result, an abrasion of the rear surface of the semiconductor substrate 11 can be prevented.

The first cleaning solution peels the surface of the substrate to expose copper particles which have penetrated into the substrate. Therefore, when forming the copper line, even if copper particles are generated on and penetrate the rear surface of the substrate after forming the copper line, the first cleaning solution cures such penetration of copper particles.

In the cleaning method according to an embodiment of the present invention, the first cleaning solution is used only in the step of forming the copper line. After that, the subsequent cleaning steps are performed after the formation of the copper line. The first cleaning solution is not used, so as to prevent the abrasion of the substrate. That is, in steps following copper line formation, a mixture of the second and third cleaning solutions may be used to clean the rear surface of the substrate, without abrasion. Thus, the cleaning method according to an embodiment of the present invention maintains a cleaning efficiency with a simplified process.

It will be apparent to those skilled in the art that various modifications and variations can be made in the present invention without departing from the spirit or scope of the invention. Thus, it is intended that the present invention covers such modifications and variations of this invention provided they come within the scope of the appended claims and their equivalents.

What is claimed is:

1. A method for cleaning a semiconductor substrate having a semiconductor device, the method comprising:
cleaning a surface of the semiconductor substrate having a copper line with a first cleaning solution including hydrofluoric acid and ultra pure water; and
cleaning the surface of the semiconductor substrate having the copper line with a mixture of a second cleaning solution including hydrogen peroxide and ultra pure water and a third cleaning solution including tetramethylammonium hydroxide and ultra pure water.

2. The method of claim 1, wherein said cleaning using the first cleaning solution is performed only during the copper line formation.

3. The method of claim 1, wherein said cleaning using the second and third cleaning solutions is performed for fabrication steps following the formation of the copper line.

4. The method of claim 1, wherein the copper line is formed as a damascene structure.

5. The method of claim 1, wherein the copper line is formed as a dual damascene structure.

6. The method of claim 1, wherein the copper line is formed on a first surface of the semiconductor substrate and wherein the first, second, and third cleaning solutions are applied to a second surface of the semiconductor substrate.

7. The method of claim 6, wherein the second surface is a rear surface having no semiconductor device thereon.

8. A method of cleaning a rear surface of a semiconductor device comprising:
exposing the rear surface to a first solution during a process step;
exposing the rear surface to mixture of a second and third solution after the process step has been performed.

9. The method of claim 8, wherein the second and third solutions are different from the first solution.

10. The method of claim 8, wherein the first solution comprises hydrofluoric acid and ultra pure water.

11. The method of claim 8, wherein the second solution comprises hydrogen peroxide and ultra pure water.

12. The method of claim 8, wherein the third solution comprises tetramethylammonium hydroxide and ultra pure water.

13. The method of claim 8, wherein the process step comprises forming a copper line.

14. The method of claim 8, wherein the process step comprises forming a copper line with a damascene process.
